(19) United States
(12) Patent Application Publication
(10) Pub. No.: US 2019/0088518 A1
(43) Pub. Date: Mar. 21, 2019

(54) SUBSTRATE SUPPORT WITH COOLED AND CONDUCTING PINS

(71) Applicant: Applied Materials, Inc., Santa Clara, CA (US)

(72) Inventors: Travis Lee KOH, Sunnyvale, CA (US); Philip Allan KRAUS, San Jose, CA (US); Wonseok LEE, Saratoga, CA (US)

(21) Appl. No.: 15/710,683

(22) Filed: Sep. 20, 2017

(51) Int. Cl. H01L 21/683; H01L 21/67; H01J 37/32; C23C 16/511; C23C 16/458; C23C 16/505; C23C 16/455

(52) U.S. Cl. CPC H01L 21/6833; H01L 21/67103; H01J 37/3244; H01J 37/32541; H01L 21/02274; C23C 16/458; C23C 16/505; C23C 16/45565; C23C 16/511

(57) ABSTRACT

Embodiments described herein generally relate to plasma assisted or plasma enhanced processing chambers. More specifically, embodiments herein relate to electrostatic chucking (ESC) substrate supports configured to provide pulsed DC voltage, and methods of applying pulsed DC voltage, to a substrate during plasma assisted or plasma enhanced semiconductor manufacturing processes.

### BACKGROUND

### Field

Embodiments described herein generally relate to processing chambers used in semiconductor manufacturing, in particular, to processing chambers having a substrate support assembly configured to bias a substrate disposed thereon, and methods of biasing the substrate.

### Description of the Related Art

Reliably producing high aspect ratio features is one of the key technology challenges for the next generation of very large scale integration (VLSI) and ultra large scale integration (ULSI) of semiconductor devices. One method of forming high aspect ratio features uses a plasma assisted etching process to form high aspect ratio openings in a material layer, such as a dielectric layer, of a substrate. In a typical plasma assisted etching process, a plasma is formed in the processing chamber and ions from the plasma are accelerated towards the substrate, and openings formed in a mask thereon, to form openings in a material layer beneath the mask surface.

Typically, the ions are accelerated towards the substrate by coupling a low frequency RF power in the range of 400 kHz to 2 MHz to the substrate thereby creating a bias voltage thereon. However, coupling an RF power to the substrate does not apply a single voltage to the substrate relative to the plasma. In commonly used configurations, the potential difference between the substrate and the plasma oscillates from a near zero value to a maximum negative value at the frequency of the RF power. The lack of a single potential, accelerating ions from the plasma to the substrate, results in a large range of ion energies at the substrate surface and in the openings (features) being formed in the material layers thereof. In addition, the disparate ion trajectories that result from RF biasing produce large angular distributions of the ions relative to the substrate surface. Large ranges of ion energies are undesirable when etching the openings of high aspect ratio features as the ions do not reach the bottom of the features with sufficiently high energies to maintain desirable etch rates. Large angular distributions of ions relative to the substrate surface are undesirable as they lead to deformations of the feature profiles, such as necking and bowing in the vertical sidewalls thereof.

Accordingly, there is a need in the art for the ability to provide narrow ranges of high energy ions with low angular distributions at the material surface of a substrate during a plasma assisted etching process.

### SUMMARY

The present disclosure generally relates to plasma assisted or plasma enhanced processing chambers. More specifically, embodiments herein relate to electrostatic chucking (ESC) substrate supports configured to provide pulsed DC voltage to a substrate disposed thereon during plasma assisted or plasma enhanced semiconductor manufacturing processes, and method of providing pulsed DC voltage to the substrate.

In one embodiment, a substrate support assembly is provided. The substrate support assembly includes a substrate support formed of a dielectric material, where the dielectric material of the substrate support has a plurality of openings of a first diameter formed therethrough. The substrate support further includes a sealing lip concentrically disposed on a surface, and proximate to an edge, thereof, wherein the surface of the substrate support and sealing lip define a plenum when a substrate is clamped thereto. Herein, the substrate support has an electrode planarly disposed in, and parallel to the surface thereof. The substrate support assembly further includes a plurality of conductive pins, where each of the conductive pins is disposed through a corresponding opening of the plurality of openings. Each of the conductive pins has a second diameter that is less than the first diameter of the plurality of openings. Each respective conductive pin and opening defines a channel and the plenum and the channels form a gas volume

In another embodiment, a method for processing a substrate is provided. The method includes flowing a first gas into the processing chamber, forming a plasma from the first gas, and electrically clamping the substrate to a substrate support disposed in a processing chamber. The method further includes biasing the substrate with a first pulsed DC voltage using a plurality of conductive pins disposed through the plurality of openings and extending beyond a surface of the dielectric material of the substrate support, where each respective conductive pin and opening defines a channel. The method further includes providing a second gas to the channels.

In another embodiment, a processing chamber is provided. The processing chamber includes one or more sidewalls and a bottom, which define a processing volume, and a substrate support assembly disposed in the processing volume. The substrate support assembly includes a conductive base formed of an electrically conductive material. A substrate support is thermally coupled to the conductive base and includes a dielectric material that has a plurality of openings formed therein and an electrode planarly disposed in the dielectric material of the substrate support. The substrate support assembly further includes a plurality of conductive pins where each pin is disposed through one of the openings formed in the dielectric material of the substrate support and each respective pin and opening define a channel therebetween. Each pin of the substrate support assembly extends beyond a surface of the dielectric material of the substrate support and is electrically coupled to the conductive base. In some embodiments, the processing chamber further includes a plasma generating apparatus comprising a capacitively coupled plasma (CCP) source or an inductively coupled plasma (ICP) source electrically coupled to an RF power supply. For example, in one embodiment the plasma generating apparatus comprises a plasma electrode, disposed in the processing volume facing the substrate support, and a power conduit configured to electrically couple the plasma electrode to an RF power supply. In other embodiments, the plasma generating apparatus comprises a microwave plasma source, such as an electron cyclotron resonance plasma (ECR) source or a linear microwave plasma source (LPS), and a power conduit configured to electrically couple the microwave plasma source to a microwave power supply.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic sectional view of a processing chamber having an electrostatic chucking (ESC) substrate support with conductive pins disposed therein, according to one embodiment.

FIG. 1B is a top down view of the substrate support assembly shown in FIG. 1A.

FIG. 1C is a close up top down sectional view of a portion of the substrate support shown in FIG. 1B.

FIG. 1D is a perspective view of a portion of a conductive pin, according to one embodiment.

FIGS. 1E-1F are perspective views of portions of conductive pins, according to other embodiments.

FIG. 1G is a cross sectional view of a conductive pin disposed in a portion of a substrate support assembly, according to another embodiment.

FIGS. 2A-2B illustrates a cyclic DC voltages and an electrically floating ESC chucking voltage provided by the pulsed DC rack of FIG. 1A.

FIG. 3 is a flow diagram illustrating a method of biasing a substrate during plasma assisted or plasma enhanced processing, according to embodiments described herein.

### DETAILED DESCRIPTION

Embodiments described herein generally relate to plasma assisted or plasma enhanced processing chambers. More specifically, embodiments herein relate to electrostatic chucking (ESC) substrate supports configured to provide pulsed DC voltage to a substrate, and methods of providing pulsed DC voltage to the substrate, during plasma assisted or plasma enhanced semiconductor manufacturing processes.

The embodiments described herein provide pulsed DC power directly to the substrate through electrically conductive pins disposed through the substrate support and extending beyond a surface thereof. The substrate, resting directly on and/or in direct contact with the conductive pins, is held in position for processing by an electrostatic chucking force provided by an electrode embedded in the substrate support. Typically, the DC current running through the conductive pins heats the conductive pins through resistive loss. Therefore, the conductive pins and the substrate supports described herein are configured to maintain the conductive pins at a desirable temperature using a gas, such as helium, which may be provided to the surface of the substrate support.

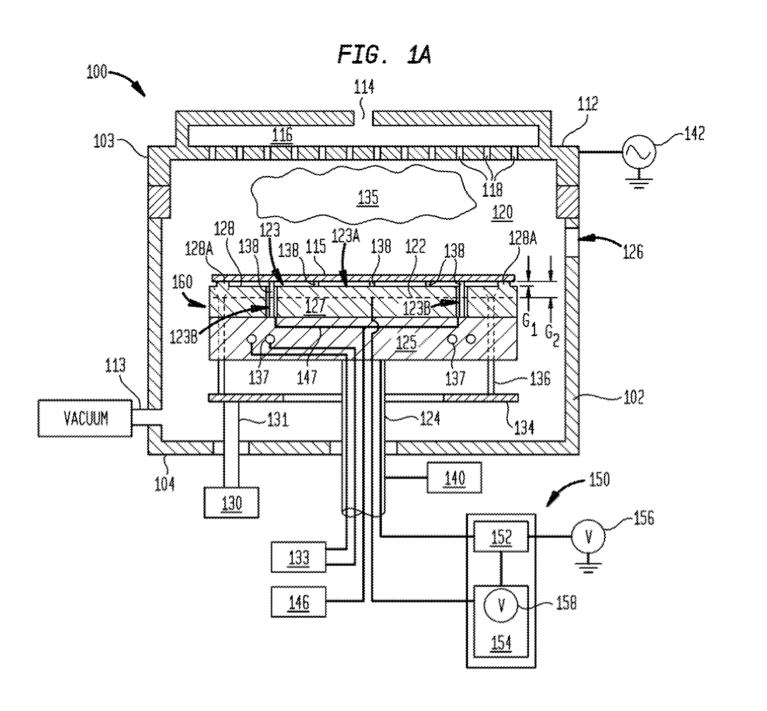

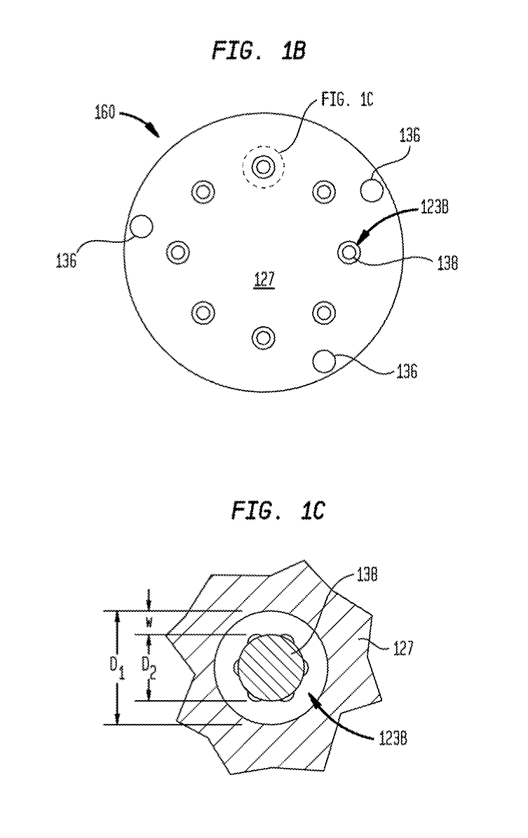

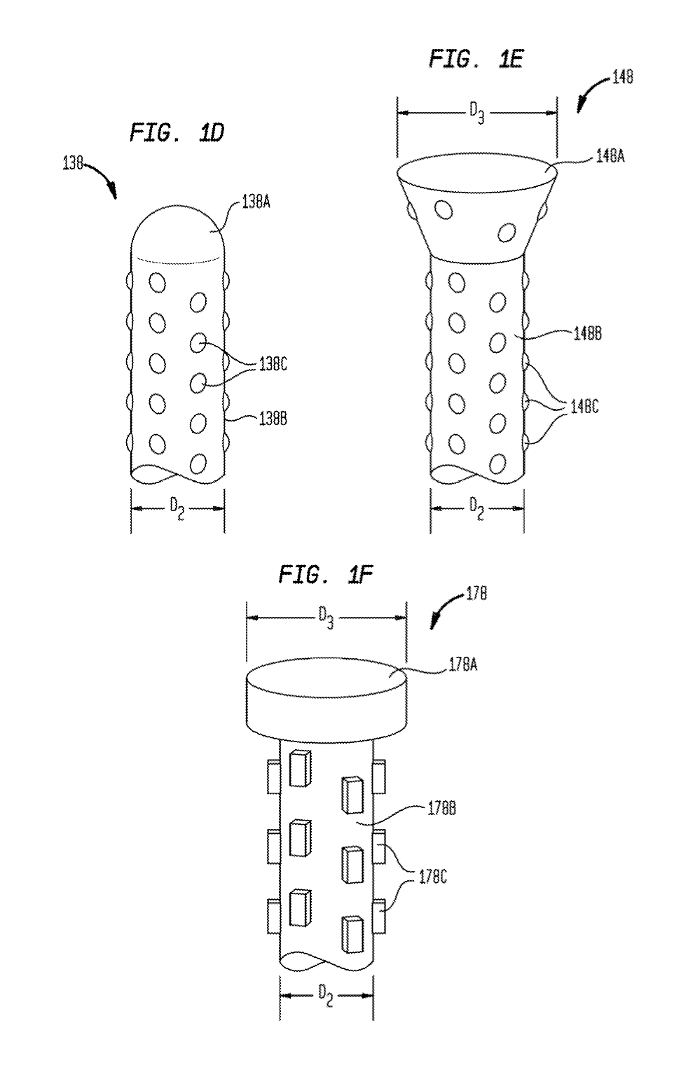

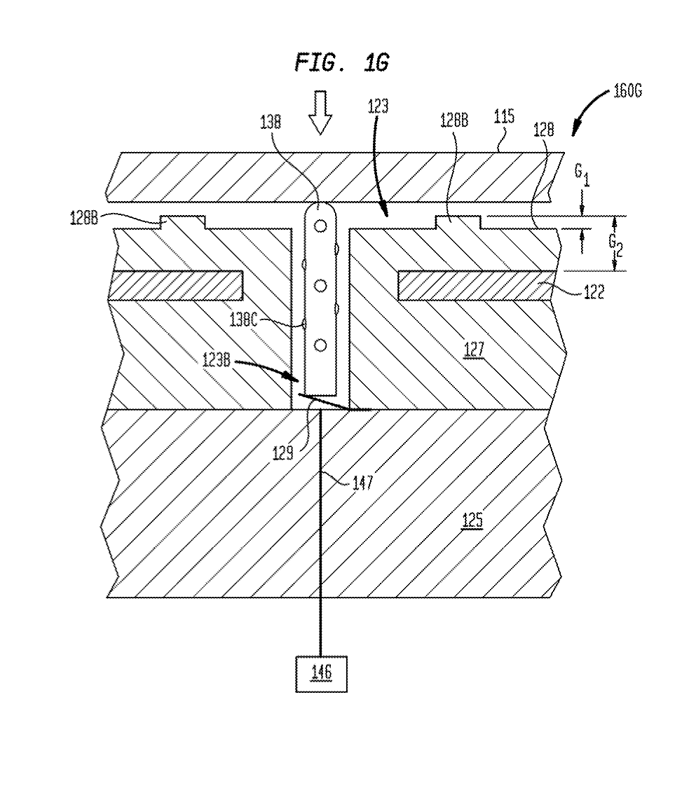

FIG. 1A is a schematic sectional view of a processing chamber 100 having an electrostatic chucking (ESC) substrate support assembly 160 disposed therein, according to one embodiment. In this embodiment, the processing chamber 100 is a plasma processing chamber, such as a plasma etch chamber, a plasma-enhanced deposition chamber, for example a plasma-enhanced chemical vapor deposition (PECVD) chamber or a plasma-enhanced atomic layer deposition (PEALD) chamber, a plasma treatment chamber, or a plasma based ion implant chamber, for example a plasma doping (PLAD) chamber.

Herein, the processing chamber 100 described is a schematic representation of a PECVD processing chamber comprising a capacitively coupled plasma (ICP) generating apparatus. The processing chamber 100 features a chamber lid 103, one or more sidewalls 102, and a chamber bottom 104 which define a processing volume 120. A showerhead 112, having a plurality of openings 118 disposed therethrough, is disposed in the chamber lid 103 and is used to uniformly distribute processing gases from a gas inlet 114 into the processing volume 120. The showerhead 112 is coupled to an RF power supply 142, or in some embodiments a VHF power supply, which ignites a plasma 135 from the processing gases through capacitive coupling therewith. In other embodiments, the plasma generating apparatus comprises an inductively coupled plasma (ICP) source electrically coupled to an RF power supply or a microwave plasma source, such as an electron cyclotron resonance plasma (ECR) source or a linear microwave plasma source (LPS), electrically coupled to a microwave power supply.

The processing volume 120 is fluidly coupled to a vacuum, such as to one or more dedicated vacuum pumps, through a vacuum outlet 113 which maintains the processing volume 120 at sub-atmospheric conditions and evacuates processing and other gases therefrom. A substrate support assembly 160, disposed in the processing volume 120 is disposed on a support shaft 124 sealingly extending through the chamber bottom 104. The support shaft 124 is coupled to a controller 140 that raises and lowers the support shaft 124, and the substrate support assembly 160 disposed thereon, to facilitate processing of the substrate 115 and transfer of the substrate 115 to and from the processing chamber 100. Typically, when the substrate support assembly 160 is in a raised or processing position, the substrate 115 is spaced apart from the showerhead 112 between about 0.2 inches and 2.0 inches, such as about 1.25 inches.

The substrate 115 is loaded into the processing volume 120 through an opening 126 in one of the one or more sidewalls 102, which is conventionally sealed with a or door or a valve (not shown) during substrate 115 processing. A plurality of lift pins 136 disposed above a lift pin hoop 134 are movable disposed through the substrate support assembly 160 to facilitate transferring of the substrate 115 thereto and therefrom. The lift pin hoop 134 is coupled to lift hoop shaft 131 sealingly extending through the chamber bottom, which raises and lowers the lift pin hoop 134 by means of an actuator 130. When the lift pin hoop 134 is in a raised position, the plurality of lift pins 136 extend above the surface of the substrate support 127 lifting the substrate 115 therefrom and enabling access to the substrate 115 by a robot handler. When the lift pin hoop 134 is in a lowered position the plurality of lift pins 136 are flush with, or below the surface of the substrate support 127 and the substrate 115 rests on a plurality of conductive pins 138 extending therethrough.

The substrate support assembly 160 herein includes a conductive base 125, a substrate support 127 thermally coupled to, and disposed on, the conductive base 125, and a plurality of conductive pins 138, disposed through the substrate support 127 that are electrically coupled to the conductive base 125. The conductive base 125 of the substrate support assembly 160 is used to regulate the temperature of the substrate support 127, and the substrate 115 disposed thereon, during processing and to provide pulsed DC power to the plurality of conductive pins. Herein, the conductive base 125 includes one or more fluid conduits 137 disposed therein that are fluidly coupled to, and in fluid communication with, a coolant source 133, such as a refrigerant source or water source. The conductive base 125 is formed of a corrosion resistant electrically and thermally conductive material, such as a corrosion resistant metal, for example aluminum, an aluminum alloy, or stainless steel. The substrate support 127 is typically formed from a dielectric material, such as a ceramic material, for example Al₂O₃, AlN, Y₂O₃, or combinations thereof. The substrate support 127 herein is thermally and fixedly coupled to the conductive base 125 with an adhesive or by suitable mechanical means.

The substrate support assembly 160 provides for biasing of the substrate 115 and clamping of the substrate 115 thereto. The substrate 115 is biased through direct electrical contact with the plurality of conductive pins 138. The plurality of conductive pins 138 are disposed through the substrate support 127 and are electrically coupled to the conductive base 125. Typically, the plurality of conductive pins 138 are formed of a corrosion resistant electrically conductive material, such as aluminum, an aluminum alloy, silicon carbide, or combinations thereof.

Herein, the conductive base 125 is electrically coupled to a bias controller 152 disposed in a pulsed DC rack 150, the bias controller 152 includes a solid state pulser/switcher that is electrically coupled to a first DC power supply 156. The first DC power supply 156 provides a high voltage (HV) DC power of between about 0 kV and about 10 kV, and the bias controller 152, through the solid state pulser/switcher, converts the HV DC power to a cyclic pulsed DC voltage having a frequency between about 10 Hz and about 100 kHZ, such as between about 500 Hz and about 10 kHZ. The cyclic pulsed DC voltage provides a pulsed DC bias to the substrate 115 through direct electrical connection therewith.

The ESC electrode 122 is electrically coupled to an electrically floating voltage source 154 disposed in the pulsed DC rack 150. The electrically floating voltage source 154 is electrically coupled to the bias controller 152 which provides a reference voltage thereto. The electrically floating voltage source 154 includes a second DC power supply 158 that provides a chucking voltage to the ESC electrode 122. The second DC power supply 158 electrically floats on the pulsed DC voltage from the bias controller 152 to provide a constant voltage difference between the DC chucking voltage provided to the ESC electrode 122, embedded in the substrate support 127, and the pulsed DC voltage (the reference voltage) provided to substrate 115. Herein, the ESC voltage is between about 0 V and about 5000 V above the pulsed DC voltage, such as between about 500 V and about 4500 V, such as between about 1000 V and about 3000 V, for example about 2500V.

The substrate 115 makes direct contact with and/or rests on the plurality of conductive pins 138 during processing. In one embodiment, the plurality of conductive pins 138 includes a plurality of pins fixedly coupled to the substrate support assembly 160 which extend above the dielectric material of the substrate support surface 128 a first distance G₁ between about 1 μm and about 10 μm, such as between about 3 μm and about 7 μm, for example about 5 μm. The substrate 115, spaced apart from the substrate support surface 128 by the first distance G₁, is securely held to the plurality of conductive pins 138 by a clamping force provided by an ESC electrode 122 embedded in the dielectric material of the substrate support 127. Herein, the ESC electrode 122 comprises one or more continuous electrically conductive material parts, such as a mesh, foil, ring, or plate planarly disposed along a plane parallel with the substrate support surface 128. The ESC electrode 122 is electrically isolated from the plurality conductive pins 138 by openings in the electrically conductive material part and by the dielectric material of the substrate support disposed between the ESC electrode and the plurality of conductive pins 138. The ESC electrode herein is spaced apart from the substrate support surface 128 by a second distance G₂ between about 100 μm and about 300 μm.

During processing, ion bombardment of the substrate 115 will heat the substrate 115 to undesirable high temperatures as the low pressure of the processing volume 120 results in poor thermal conduction between the substrate 115 and the substrate support surface 128. Further, DC current flowing through the plurality of conductive pins 138 causes undesirable heating thereof, and the substrate 115 in contact therewith, from resistive loss. Therefore, in embodiments herein, the substrate support assembly 160 is configured to provide a gas to a gas volume 123 between the substrate 115, the plurality of conductive pins 138, and the dielectric material of the substrate support 127. Herein, the gas volume 123 comprises a plenum 123A and a plurality of cooling channels 123B contiguous with the plenum 123A. The plenum 123A is defined by the substrate support surface 128, a sealing lip 128A concentrically disposed on the substrate support surface 128 and proximate to a circumference thereof, and a substrate 115 clamped to the substrate support 127. Typically, the sealing lip 128A is formed of the dielectric material of the substrate support 127.

Each of the plurality of cooling channels 123B is respectively defined by an opening formed in the dielectric material of the substrate support 127 and one of the plurality of conductive pins 138. The gas, typically an inert thermally conductive gas such as helium, is provided to the gas volume 123 by a gas conduit 147 disposed through the conductive base 125. The gas conduit 147 is fluidly coupled to, and in fluid communication with, a gas source 146. The gas thermally couples the substrate 115 and the plurality of conductive pins 138 to the conductive base 125 of the substrate support 127 to increase the heat transfer therebetween. Typically, a gas pressure in the gas volume 123 is between about 1 Torr and about 100 Torr, such as between about 1 Torr and about 20 Torr. In other embodiments, the backside conduit 147 is further disposed through the substrate support 127 and provides the gas through an opening formed in the substrate support surface 128. In some embodiments, the substrate support assembly 160 further includes a pumping channel (not shown) fluidly coupled to the gas volume 123 and configured to provide a flow of gas through the gas volume 123 and cooling surfaces of the substrate 115 and substrate support assembly 160 through convective heat transfer.

FIG. 1B is a top down view of the substrate support assembly 160 shown in FIG. 1A. FIG. 1C is a close up top down sectional view of a portion of the substrate support 127 shown in FIG. 1B. As shown in FIG. 1C, an opening formed in the dielectric material of the substrate support 127 has a first diameter D₁ that is greater than a second diameter D₂ of a conductive pin 138 defining a channel width W of the cooling channel 123B. The channel width W herein is between about 0.1 mm and about 5 mm, such as between about 0.1 mm and about 4 mm, such as between about 1 mm and about 3 mm, for example about 2 mm.

FIG. 1D is a perspective view of a portion of one of the plurality of conductive pins 138 shown in FIGS. 1A-1C, according to one embodiment. Herein, the conductive pin 138 includes a domed pin head 138A and a pin shaft 138B. The domed shape of the pin head 138A provides physical contact with a substrate without risking scratching from sharp edges. In other embodiments, the pin head 138A is substantially flat with chamfered edges. In some embodiments, the pins shaft 138B further includes surface features consisting of a laterally-extending shape, such as a plurality of protuberances 138C, extending from a longitudinal outer surface thereof. The plurality of protuberances 138C provide increased surface area on the conductive pin 138 and/or turbulation of the gas as it travels over the longitudinal surface of the pin shaft 138B between the plurality of conductive pins 138 and the conductive base 125 of the substrate support 127 to increase conductive and/or convective heat transfer therebetween. The surface features herein consist of protuberances (bumps) and other protrusions formed on the surface of the conductive pins 138. In some embodiments, the surface features are formed at the same time, and of the same material, as the conductive pins 138, such as in a casting process. In other embodiments, the surface features are formed on the conductive pins 138 through a deposition process, such as a physical vapor deposition process, a CVD process, an electroplating process, or any other suitable process for modifying the surface of the conductive pin and/or forming layers of material thereon. Typically, the protuberances 138C are formed of the same material as the conductive pin 138, such as aluminum, an aluminum alloy, or silicon carbide and comprise any suitable shape. In some embodiments, the surface features are protrusions such as rectangular columns (shown in FIG. 1F) or other columns, such as oval, square, rectangular, triangular, polygonal, irregular shapes, or combinations thereof. In other embodiments, a surface feature for increasing surface are of the conductive pin and/or providing turbulent gas flow through the plurality of cooling channels 123B comprises a roughened outer surface of the pin shaft 138B. In other embodiments, the pin head 138A has a flat surface. In some embodiments, the plurality of conductive pins 138 do not have surface features thereon.

FIGS. 1E-1F—are perspective views of portions of conductive pins, according to other embodiments. In FIG. 1E a conductive pin 148 includes a pin shaft 148B with a plurality of protuberances 148C extending from the longitudinal outer surface thereof and a pin head 148A disposed on the pin shaft 148B, the pin head 148A having tapered sides and a contact surface diameter D₃ that is larger than the second diameter D₂ of the pin shaft 138B. The expanding shape of the pin head 148A provides a wide contact area between the conductive pin 148 and a substrate. In some embodiments, the edges of the pin head 148A are rounded to reduce the opportunity for scratching of a substrate disposed thereon. In FIG. 1F a conductive pin 178 includes a pin shaft 178B with plurality of rectangular shaped protrusions 178C extending from the longitudinal outer surface thereof and a pin head 178A disposed on the pin shaft 178B, the pin head having a cylindrical shape and a contact surface diameter D₃ that is larger than the second diameter D₂ of the pin shaft 178B. In other embodiments, the conductive pins 138, 148, or 178 are formed to have a turbulizing shape such as a screw shape, a spiral shape, a waveform shape, or a random undulating shape.

In some embodiments, surface features are formed on inner surfaces (inner walls) of the openings in the substrate support 127 that, with the plurality of conductive pins 138, define the plurality of cooling channels 123B. Herein, surface features formed on or of the inner walls of the openings in the substrate support 127 consist of protuberances extending from surfaces thereof, protrusions extending from the surfaces thereof, roughening of the inner wall surface, forming the inner walls to have a turbulizing shape, such as a threaded inner wall surface, or an undulating inner wall surface, or combinations thereof.

FIG. 1G is a cross sectional view of a conductive pin disposed in a portion of a substrate support assembly, according to another embodiment. In this embodiment, the conductive pin 138 is disposed on a conductive resilient member 129 positioned between the conductive pin 138 and coupled to the conductive base 125. When electrically clamped to the substrate support 127, the substrate 115 pushes the conductive pin 138 towards the conductive base 125. The substrate 115 rests directly on a plurality of mesas 128B disposed on the substrate support surface 128 and the conductive resilient member 129 provides an upward force against the conductive pin 138 which maintains contact with the substrate 115. Herein, the plurality of protuberances 138C center the conductive pin 138 in the cooling channel 123B and the conductive pin 138 is maintained about vertically when the substrate 115 is in contact therewith. Typically, the substrate 115 is spaced apart from the substrate support surface 128 by a plurality of mesas 128B formed of the dielectric material of the substrate support 127 at a distance of G₁. In some embodiments, the plurality of mesas 128B are formed by texturizing the substrate support surface 128 so that the contact area between the substrate support surface 128 and the substrate 115 is less than the a surface area of the substrate 115 to allow gas into the plenum 123 defined therebetween.

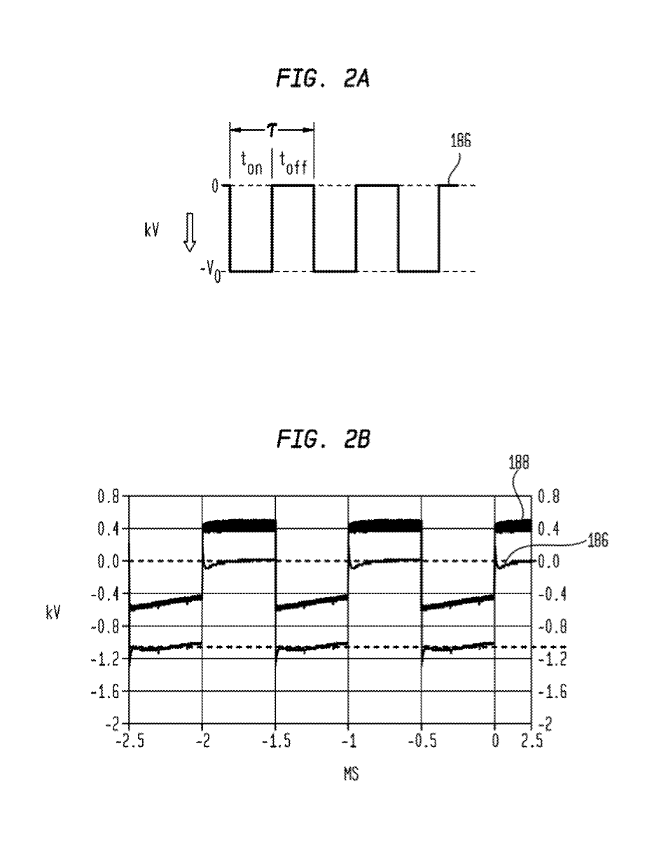

FIG. 2A illustrates a cyclic DC voltage, such as the cyclic DC voltage 186 shown in FIG. 2B, provided by a bias controller, such as the bias controller 152 shown in FIG. 1A, where the cyclic DC voltage 186 cycles from 0 volts to −V₀ in a cycle time of T FIG. 2B illustrates an ESC DC voltage 188 electrically floating on the cyclic DC voltage 186. In FIG. 2B, the cyclic DC voltage 186, provided to a plurality of conductive pins and a substrate disposed thereon, cycles between about 0 V and about −1000 V at a frequency of 1 kHz. The ESC DC voltage 188 is provided by an ESC controller coupled to a static DC power supply of about 500V. The ESC DC voltage 188 electrically floats on the cyclic DC voltage 186 thereby providing a constant potential of about 500V between the substrate and the ESC electrode and thereby a constant clamping force therebetween.

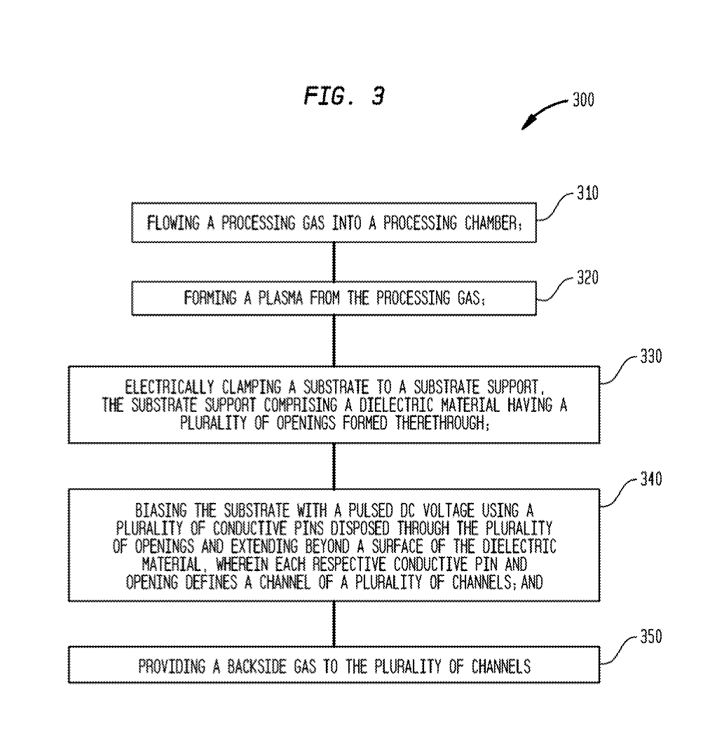

FIG. 3 is a flow diagram illustrating a method 300 of biasing a substrate during plasma assisted processing, according to embodiments described herein. At 310, the method 300 includes flowing a processing gas into the processing chamber and at 320 the method 300 includes forming a plasma from the processing gas.

At 330 the method 300 includes electrically clamping a substrate to a substrate support, such as the substrate support 127 described in FIG. 1. The clamping force is provided by an ESC electrode planarly disposed parallel the substrate support surface and embedded in the dielectric material of the substrate support. The ESC electrode is coupled to an ESC power which electrically floats on a pulsed DC power supply used to bias the substrate. In one embodiment, the constant electrically floating DC clamping voltage is between about 0V and about 5000 V, such as between about 500 V and about 4500 V, such as between about 1000 V and about 3000 V, for example about 2500 V. Herein, the substrate support is formed of a dielectric material having a plurality of openings formed therethrough, the plurality of openings having a first diameter.

At 340 the method 300 includes biasing the substrate using a plurality of conductive pins each disposed through a corresponding opening of the plurality of openings. Each of the plurality of conductive pins extends beyond a surface of the dielectric material and the substrate is in direct electrical contact therewith. Herein, each of the plurality of conductive pins has a second diameter that is less than the first diameter of a corresponding opening of the plurality of openings so that each respective conductive pin and opening defines a channel.

At 350 the method 300 includes providing a chemically inert thermally conductive gas, such as Helium, to one or more of the plurality of channels through gas conduits in fluid communication therewith. In some embodiments, the plurality of conductive pins comprise one or more surface features for turbulizing a gas flow through the channels thereby increasing the heat transfer between the conductive pin and dielectric material of the substrate support. In other embodiments, one or more surface features are formed on and/or in an inner wall of one or more of the plurality of openings. It should be noted that the plasma may also be formed after operation 320, after operation 330, after operation 340, or after operation 350.

The substrate support assemblies and methods described herein enable direct pulsed DC biasing of a substrate during plasma assisted processing that is compatible with use of an electrostatic clamping force. Pulsed DC biasing allows for increased control of ion energy and angular distribution at the substrate surface and in feature openings formed therein. This increased control is desirable at least in forming high aspect ratio features and/or other features requiring a straight etch profile, such as high aspect ratio etching in dielectric materials for memory devices, including non-volatile flash memory devices and dynamic random access memory devices, and in silicon etching for shallow trench isolation (STI) applications or to form silicon fins used in FinFET devices.

While the foregoing is directed to embodiments of the present disclosure, other and further embodiments of the disclosure may be devised without departing from the basic scope thereof, and the scope thereof is determined by the claims that follow.

1. A substrate support assembly, comprising:
a substrate support formed of a dielectric material, the dielectric material having a plurality of openings of a first diameter formed therethrough, the substrate support comprising a sealing lip concentrically disposed on a surface, and proximate to an edge thereof, wherein the surface of the substrate support and sealing lip define a plenum when a substrate is clamped thereto, and an electrode planarly disposed in, and parallel to the surface of, the substrate support; and
a plurality of conductive pins, each conductive pin disposed through a corresponding opening of the plurality of openings and having a second diameter that is less than the first diameter, wherein each respective conductive pin and opening defines a channel, and wherein the plenum and the channels form a gas volume.

2. The substrate support assembly of claim 1, further comprising a conductive base thermally coupled to the substrate support.

3. The substrate support assembly of claim 2, further comprising a gas conduit disposed through the conductive base for providing a gas to the gas volume, wherein the gas conduit is in fluid communication with the gas volume.

4. The substrate support assembly of claim 1, wherein the electrode is a conductive mesh, foil, or plate.

5. The substrate support assembly of claim 1, wherein the electrode is electrically isolated from the plurality of conductive pins.

6. The substrate support assembly of claim 2, wherein the conductive base comprises an electrically conductive material.

7. The substrate support assembly of claim 6, wherein the plurality of conductive pins is electrically coupled to the conductive base.

8. The substrate support assembly of claim 1, wherein one or more of the plurality of conductive pins has a surface feature disposed on an outer surface thereof, the surface feature consisting of a plurality of protuberances, a plurality of protrusions, a roughened outer surface, or combinations thereof.

9. The substrate support assembly of claim 7, wherein each of the conductive pins is disposed on, or coupled to, a resilient member disposed in the substrate support assembly.

10. The substrate support assembly of claim 7, wherein one or more of the plurality of conductive pins are fixedly coupled to the substrate support assembly and extend beyond the surface of the substrate support between about 1 μm and about 10 μm.

11. The substrate support assembly of claim 4, further comprising a pumping conduit disposed through a conductive base, wherein the pumping conduit is in fluid communication with the gas volume to form a gas evacuation path, and wherein the conductive base is thermally coupled to the substrate support.

12.-15. (canceled)

16. A processing chamber, comprising:
one or more sidewalls and a bottom defining a processing volume; and
a substrate support assembly disposed in the processing volume, comprising:
a conductive base formed of an electrically conductive material;
a substrate support thermally coupled to the conductive base, the substrate support comprising a dielectric material having a plurality of openings formed therein, and an electrode planarly disposed in the dielectric material of the substrate support; and
a plurality of conductive pins, each pin disposed through one of the openings, each respective pin and opening defining a channel therebetween, wherein each pin extends beyond a surface of the dielectric material and is electrically coupled to the conductive base.

17. The processing chamber of claim 16, further comprising a gas conduit disposed through the conductive base for providing a gas to the channels, wherein the gas conduit is in fluid communication with the channels.

18. The processing chamber of claim 17, wherein the electrode is electrically isolated from the conductive pins.

19. The processing chamber of claim 18, wherein one or more of the conductive pins has a surface-area-increasing feature consisting of a laterally-extending shape, one or more surface features disposed on outer surfaces of the one or more conductive pins, or combinations thereof.

20. The processing chamber of claim 16, wherein one or more of the plurality of conductive pins comprises a material selected from the group consisting of aluminum, an aluminum alloy, silicon carbide, and combinations thereof.
